(19) United States
(12) Patent Application Publication
(10) Pub. No.: US 2024/0355702 A1
(43) Pub. Date: Oct. 24, 2024

(54) INTEGRATED CIRCUIT PACKAGES WITH DAMPENERS TO REDUCE VIBRATION EFFECTS

(71) Applicants: Phil Geng, Washougal, WA (US); Donald Tiendung Tran, Phoenix, AZ (US); Srikant Nekkanty, Spicewood, TX (US); Baris Bicen, Chandler, AZ (US); James Trevor Goulding, Sherwood, OR (US); Jeffory L. Smalley, East Olympia, WA (US); Steven Adam Klein, Chandler, AZ (US); Andres Ramirez Macias, Zapopan (MX)

(72) Inventors: Phil Geng, Washougal, WA (US); Donald Tiendung Tran, Phoenix, AZ (US); Srikant Nekkanty, Spicewood, TX (US); Baris Bicen, Chandler, AZ (US); James Trevor Goulding, Sherwood, OR (US); Jeffory L. Smalley, East Olympia, WA (US); Steven Adam Klein, Chandler, AZ (US); Andres Ramirez Macias, Zapopan (MX)

(21) Appl. No.: 18/756,860

(22) Filed: Jun. 27, 2024

(51) Int. Cl. H01L 23/367; H01L 23/00; H01L 23/498

(52) U.S. Cl. CPC H01L 23/367; H01L 23/49816; H01L 23/562

(57) ABSTRACT

Integrated circuit packages with dampeners to reduce vibration effects are disclosed. An example apparatus comprises a substrate, a semiconductor die carried by the substrate, and a dampener carried by the substrate. Further, the example dampener is dimensioned to interface with a heatsink when the heatsink is thermally coupled to the semiconductor die.

### BACKGROUND

The demand for greater computing power and faster computing times continues to grow. This has led to higher density connectors on computer hardware components to transfer signals more quickly. Some processor chips (e.g., land grid array (LGA) processor chip, ball grid array (BGA) processor chip, etc.) are communicatively coupled to printed circuit boards (PCBs) via sockets constructed to receive and electrically couple to contacts on the processor chips. Often a heatsink is mechanically and thermally coupled to the processor chip on a side opposite the socket to facilitate the dissipation of heat generated by the processor chip.

### BRIEF DESCRIPTION OF THE DRAWINGS

FIG. 1 is an exploded view of an example integrated circuit (IC) package heat dissipating component stack constructed in accordance with teachings disclosed herein.

FIG. 2A a simplified, cross-sectional view of the example component stack of FIG. 1 prior to an example heatsink being pressed down onto an example IC package.

FIG. 2B is another simplified, cross-sectional view of the example components of FIG. 2A after the example heatsink has been pressed down onto the example IC package.

FIG. 3 is a cross-sectional view of an example first implementation of the IC package of FIGS. 2A and 2B constructed in accordance with teachings disclosed herein.

FIG. 4 is a cross-sectional view of an example second implementation of the IC package of FIGS. 2A and 2B constructed in accordance with teachings disclosed herein.

FIG. 5 is a cross-sectional view of an example third implementation of the IC package of FIGS. 2A and 2B constructed in accordance with teachings disclosed herein.

FIG. 6 is a cross-sectional view of an example fourth implementation of the IC package of FIGS. 2A and 2B constructed in accordance with teachings disclosed herein.

FIGS. 7A-7I are top views of different example implementations of the example dampener and the example IC package 106 of FIGS. 2A and 2B.

FIG. 8 is a top view of a wafer including dies that may be included in an IC package constructed in accordance with teachings disclosed herein.

FIG. 9 is a cross-sectional side view of an IC device that may be included in an IC package constructed in accordance with teachings disclosed herein.

FIG. 10 is a cross-sectional side view of an IC device assembly that may include an IC package constructed in accordance with teachings disclosed herein.

FIG. 11 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

As the computing industry evolves, the demand for higher input/output (IO) speeds and throughput continues to increase. Computer hardware components, such as central processing units (CPUs), graphical processing units (GPUs), memory, motherboards, etc., are often connected by electrical connectors. For example, a CPU in a server system may be connected to one or more other components by a cable connector that connects to a mating connector on a substrate or board of the CPU. A recent trend has been to increase the IO capability by adding more pin counts to the connectors on the CPUs. However, traditional cable connectors use two rows of pins, which are very low density. As a result, adding more pins to the cable connector requires more space on the board and therefore increases the overall size of the package. In some instances, there may not be enough space to add more pins. Manufacturers desire to keep the package size small while still increasing the IO capabilities.

Some example cable connectors use socket connector type connections. Socket connectors have an array or grid of socket pins. The socket pins are relatively thin and can be placed in a high-density arrangement, thereby improving the IO capability of a system. These socket pins are relatively fragile. Further, the socket pins are usually exposed and, thus, are prone to damage. Therefore, when a person is handling the socket connector, the person has to be cautious not to touch the socket pins or hit the socket pins on any foreign object, as this could easily bend or break the socket pins.

A socket substrate includes such pins to contact pads on the surface of an opposing substrate. Typically, a compression or loading mechanism is used in order to deflect the pins so with sufficient force (e.g., at least 10 grams-force per pin) to ensure consistent and reliable electrical contact between the components. In some examples, if the socket substrate is subject to vibrations (e.g., during shipping, during vibrational testing, etc.), the pins may move (e.g., slide) relative to the pads. In such examples, the pins may scratch and/or damage the opposing pads (e.g., via fretting) which, in turn, wears down coatings on the pads that prevent oxidation. When the coatings are scratched away, the underlying material of the contact pads (e.g., nickel, copper, etc.) is exposed to environmental conditions (e.g., moisture, air, etc.). The underlying material can oxidize, which may reduce the electrical conductivity between the pins and associated pads.

Examples disclosed herein provide dampeners (e.g., dampening bodies, compressibly resilient materials, etc.) for use in socket-based architectures to mitigate risk of damage to pad surfaces. Examples disclosed herein position dampeners to resist (e.g., reduce) movement of an example socket substrate relative to an associated integrated circuit (IC) package (e.g., processor chip) and, thus, resist (e.g., reduce) movement of associated pins of the socket substrate relative to the IC package. For example, disclosed examples include dampeners that are positioned to interface with an example heatsink that presses an IC package against the socket substrate to resist movement of the IC package relative to such a substrate. Accordingly, examples disclosed herein reduce and/or eliminate fretting on pad surfaces by dampening vibrations in an associated IC package. Examples disclosed herein improve the electrical connectivity in such an IC package by increasing the number of socket pins and mitigating fretting between the socket pins and any associated pad surfaces.

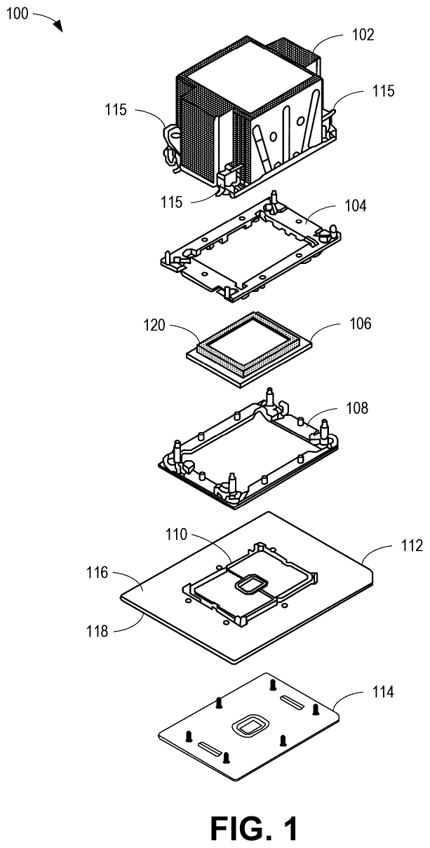

FIG. 1 illustrates an exploded view of an example integrated circuit (IC) package heat dissipating component stack 100 constructed in accordance with teachings disclosed herein. In FIG. 1, the component stack 100 includes a heatsink 102, a carrier (e.g., a package carrier, a carrier plate) 104, an integrated circuit (IC) package 106, a bolster plate 108, a socket 110 coupled to a printed circuit board (PCB) (e.g., a motherboard) 112, and a back plate 114.

In this example, the IC package 106 includes one or more electrical circuits on a semiconductor substrate. In some examples, the IC package 106 can perform processing functions, memory functions, and/or any other suitable functions. The IC package 106 can include any type of processing circuitry, including programmable microprocessors, one or more FPGAs, one or more CPUs, one or more GPUs, one or more DSPs, one or more XPUs, one or more ASICs, and/or one or more microcontrollers. In FIG. 1, the IC package 106 is a land grid array (LGA) processor chip. Additionally or alternatively, the IC package 106 can be one of a ball grid array (BGA) processor chip or a pin grid array (PGA) processor chip instead. Further, other types of IC packages can be used in the component stack 100 instead of a processor chip (e.g., a memory chip). In FIG. 1, the carrier 104 is used to couple the heatsink 102 to the IC package 106 prior to assembly of the entire component stack 100. In some examples, the carrier 104 is omitted and the assembly process involves inserting the IC package 106 into the socket 110 and then attaching the heatsink 102.

In FIG. 1, the heatsink 102 is couplable (e.g., thermally couplable) to the IC package 106 to dissipate heat therefrom. In FIG. 1, the heatsink 102 is mechanically coupled to the back plate 114 via fixture elements, loading mechanisms, or fasteners 115 to place the components between the heatsink 102 and the back plate 114 within the component stack 100 in compression when assembled. In some examples, the heatsink 102 is coupled to the back plate 114 via the bolster plate 108 positioned therebetween. More particularly, as shown in FIG. 1, the bolster plate 108 is couplable to a top surface 116 of the PCB 112 while the back plate 114 is couplable to a bottom surface 118 of the PCB 112 opposite the bolster plate 108. In this manner, the PCB 112 is sandwiched between the bolster plate 108 and the back plate 114. The bolster plate 108 is constructed to surround the socket 110 positioned on the top surface 116 of the PCB 112.

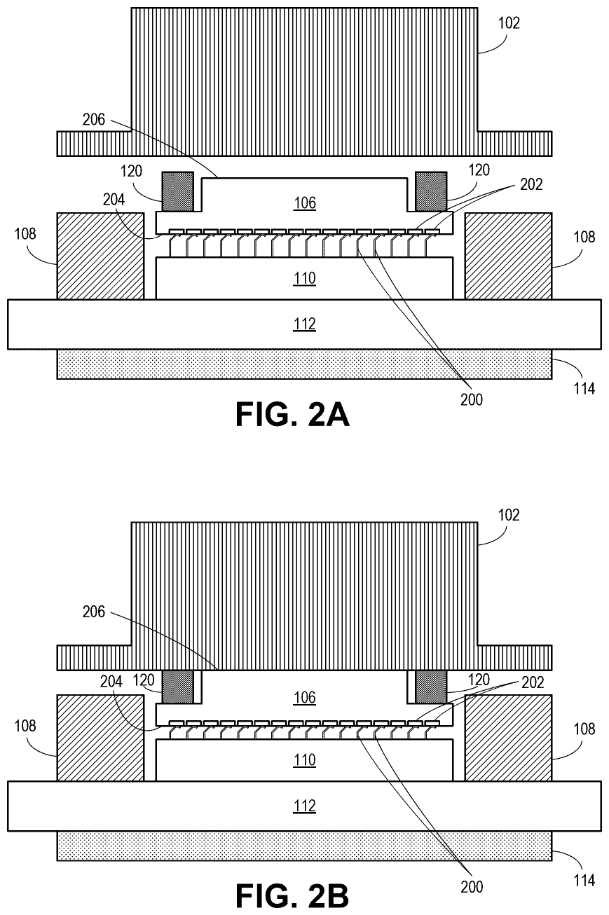

The socket 110 communicatively couples the IC package 106 to the printed circuit board 112. In FIG. 1, the socket 110 is an LGA socket, which includes a plurality of pins within the socket arranged to interface (e.g., electrically couple) with corresponding contacts/lands/pads on the IC package 106. In other examples, the socket 110 can be implemented by any other type of socket (e.g., a BGA, a PGA, etc.) suitable to receive and interface with the IC package 106. The compression created by the mechanical coupling of the heatsink 102 to the back plate 114 via the fasteners 115 serves to ensure that corresponding connectors (e.g., pins, lands, etc.) on the socket 110 and the IC package 106 remain in contact. However, as previously mentioned, the pins on the socket 110 are fragile and can subject corresponding contacts on the IC package 106 to fretting (e.g., during vibrations or other movement). In accordance with teachings disclosed herein, the example component stack 100 includes an example dampener 120 positioned on, carried by, and/or included with the IC package 106 to mitigate against fretting, as described in detail in connection with at least FIGS. 2A-7I.

FIG. 2A is a simplified cross-sectional view of the example component stack 100 of FIG. 1 prior to the heatsink 102 being pressed down onto the example IC package 106. FIG. 2B is another simplified cross-sectional view of the component stack 100 of FIG. 1 after the example heatsink 102 has been pressed down onto the example IC package 106. In FIGS. 2A and 2B, the component stack 100 includes the heatsink 102 of FIG. 1, the IC package 106 of FIG. 1, the bolster plate 108 of FIG. 1, the socket 110 of FIG. 1, the printed circuit board 112 of FIG. 1, the back plate 114 of FIG. 1, and the dampener 120 of FIG. 1 (the carrier 104 of FIG. 1 and the fasteners 115 of FIG. 1 are omitted in FIGS. 2A and 2B for purposes of explanation). Further, the example component stack 100 of FIGS. 2A and 2B illustrates example pins 200 in contact with example pads 202 on the IC package 106. As such, an example surface 204 (e.g., bottom surface) of the IC package 106 can include a BGA or an LGA.

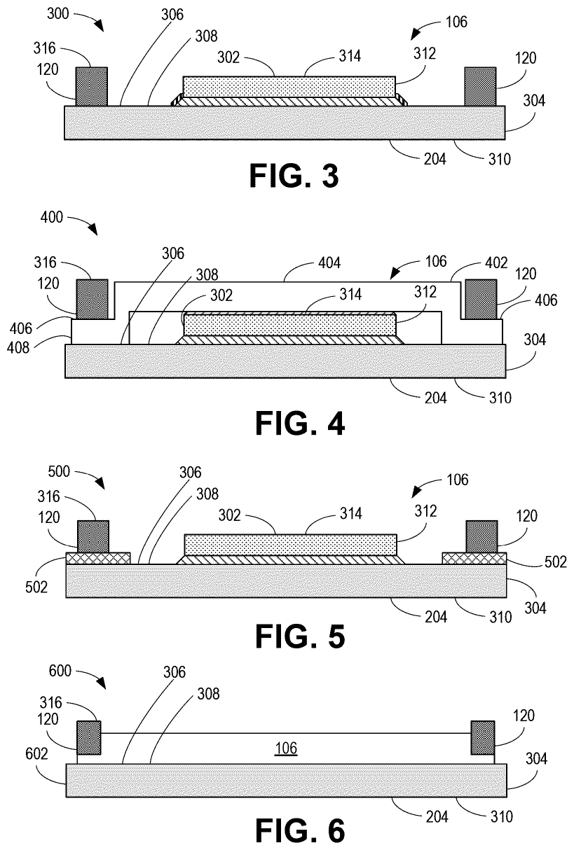

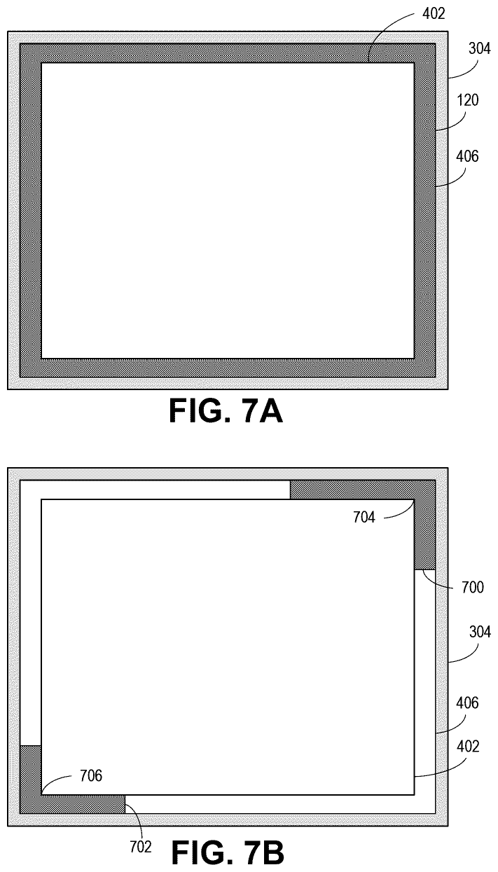

In FIG. 2A, the example heatsink 102 is shown separate (e.g., removed, disassembled, etc.) from the IC package 106. Alternatively, in FIG. 2B, the example heatsink 102 is shown coupled to (e.g., in contact with, thermally coupled with, etc.) the IC package 106. In particular, the example heatsink 102 thermally couples to an example semiconductor die included in the IC package 106, as described in detail in connection with at least FIGS. 3-7I. In some examples, the heatsink 102 thermally couples to such a semiconductor die via an integrated heat spreader (IHS), as described in detail in connection with at least FIG. 4.

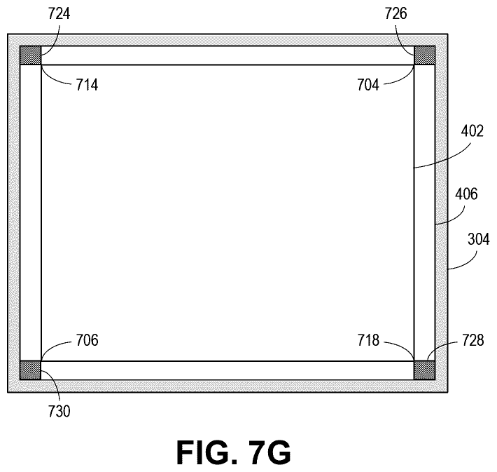

In some examples, when the heatsink 102 is separate from the IC package 106 (FIG. 2A), the dampener 120 extends from the IC package 106 past another example surface 206 (e.g., top surface) of the IC package 106. Further, the example dampener 120 is dimensioned to interface with the heatsink 102 when, for example, the heatsink 102 is thermally coupled to the IC package 106 (FIG. 2B). More particularly, due to the dampener 120 extending beyond the top surface 206, in some examples, when the heatsink 102 is pressed against the top surface 206, the dampener 120 is in compression. Accordingly, in some examples, the dampener 120 can be a compressibly resilient material. In some examples, the dampener 120 includes foam, silicone, polyurethane, etc. In some examples, the dampener 120 is a dampening body having a generally rectangular cross-section, a generally circular cross-section, a generally ovular cross-section, a generally triangular cross-section, a generally trapezoidal cross-section, and/or a cross-section of any other suitable shape. In some examples, the dampener 120 is included in an array or pattern of dampeners, as described in detail in connection with at least FIGS. 7A-7I.

FIGS. 3-5 illustrate cross-sectional views of different implementations of the IC package 106 of FIGS. 1-2B. In other words, any of the examples described in connection with FIGS. 3-5 can be used to implement the IC package 106 of FIGS. 1-2B. Turning to FIG. 3, a cross-sectional view of an example first implementation 300 of the IC package 106 is shown. In the example of FIG. 3, the IC package 106 includes an example semiconductor die 302 carried by an example package substrate 304. In particular, the example package substrate 304 includes a surface 306 (e.g., on a first side 308) of the package substrate 304 to support the semiconductor die 302. In some examples, the package substrate 304 is an interposer. For example, the IC package 106 includes another package substrate interconnecting the semiconductor die 302 and the interposer.

In the example of FIG. 3, the dampener 120 is carried by (e.g., supported on) the surface 306 of the package substrate 304. In some examples, the dampener 120 is coupled directly to the surface 306 of the package substrate 304 via an adhesive (e.g., an epoxy, a liquid adhesive, double sided tape, etc.). The surface 306 of the example package substrate 304 is opposite an example second side 310 of the package substrate 304. The example second side 310 includes the bottom surface 204 (including the pads 202 of FIGS. 2A and 2B) of the IC package 106.

The example dampener 120 is positioned adjacent a side 312 of the semiconductor die 302. Further, the example dampener 120 is laterally offset from the semiconductor die 302 along the surface 306 of the package substrate 304. As such, the example dampener 120 is spaced apart from the side 312 of the semiconductor die 302. Additionally, the example dampener 120 extends farther away from the package substrate 304 than the semiconductor die 302. As shown in FIG. 3, the example dampener 120 extends farther away from the package substrate 304 than an example backside 314 (facing away from the package substrate 304) of the semiconductor die 302. In other words, the backside 314 of the semiconductor die 302 is closer to the package substrate 304 than an end 316 of the dampener 120.

In the example first implementation 300, the semiconductor die 302 is a bare die exposed on the package substrate 304. In other words, in this example, the IC package 106 is a bare die package. As such, the example heatsink 102 (FIGS. 1, 2A, and 2B) is couplable (e.g., directly couplable) with the semiconductor die 302 via the backside 314 without a package lid or IHS positioned therebetween. In some examples, a thermal interface material (TIM) may still be positioned between the backside 314 of the semiconductor die 302 and the heatsink 102. The example dampener 120 is dimensioned and/or otherwise positioned to interface with the heatsink 102 when the heatsink 102 is thermally coupled to the semiconductor die 302. For example, referring to FIGS. 2B and 3, the dampener 120 is to be held in compression between the package substrate 304 and the heatsink 102 when the heatsink 102 is thermally coupled to the semiconductor die 302. More particularly, the dampener 120 can be compressed between the heatsink 102 and the surface 306 of the package substrate 304. The example dampener 120 includes materials that enable the dampener 120 to be compressibly resilient. As such, the example dampener 120 resists movement between the heatsink 102 and the IC package 106 when the heatsink 102 is thermally coupled to the semiconductor die 302. This, in turn, can reduce movement between the IC package 106 and the socket 110 (FIGS. 1, 2A, and 2B), thereby reducing fretting of the contact pads 202 on the IC package 106.

FIG. 4 is an example second implementation 400 of the IC package 106 of FIGS. 1, 2A, and 2B. The example second implementation 400 of FIG. 4 is similar to the example first implementation 300 of FIG. 3. However, the example second implementation 400 further includes an example IHS 402 (e.g., a package lid) enclosing the semiconductor die 302. The example IHS 402 includes an example outer surface 404 that interfaces with the heatsink 102 (instead of the semiconductor die 302 being directly coupled (e.g., within or without a thermal interface material) to the heatsink 102 as in FIG. 3) when the heatsink 102 is coupled to the IC package 106 (FIG. 2B). In other words, the example IHS 402 separates the semiconductor die 302 from the heatsink 102. The example IHS 402 conducts heat from the package substrate 304 and into the heatsink 102 when the heatsink 102 is coupled to the IC package 106 (FIG. 2B). In some instances, a thermal interface material (TIM) is disposed between the IHS 402 and the heatsink 102 to facilitate heat transfer therebetween. Further, in some examples, a TIM can also be used between the IHS 402 and the heatsink 102.

Further, a portion of the IHS 402 extends across the surface 306 of the package substrate 304 to separate the dampener 120 from the package substrate 304. For example, the portion of the IHS 402 may be an example ledge 406 (e.g., step, protrusion, etc.) that is recessed relative to the outer surface 404. The example dampener 120 is positioned on the ledge 406. As such, the dampener 120 is positioned (e.g., elevated) by the ledge 406 to interface with the heatsink 102 when the heatsink 102 is coupled to the IC package 106. Further, the example dampener 120 extends farther away from the package substrate 304 than the outer surface 404 is from the package substrate 304 (e.g., in the disassembled position of FIG. 2A). Accordingly, the example dampener 120 is held in compression (e.g., squeezed) between the IHS 402 (e.g., the ledge 406 of the IHS 402) and the heatsink 102 when the heatsink 102 is coupled to the IC package 106 (FIG. 2B). In some examples, the dampener 120 is coupled to the HIS 404 via an adhesive (e.g., an epoxy, a liquid adhesive, double sided tape, etc.).

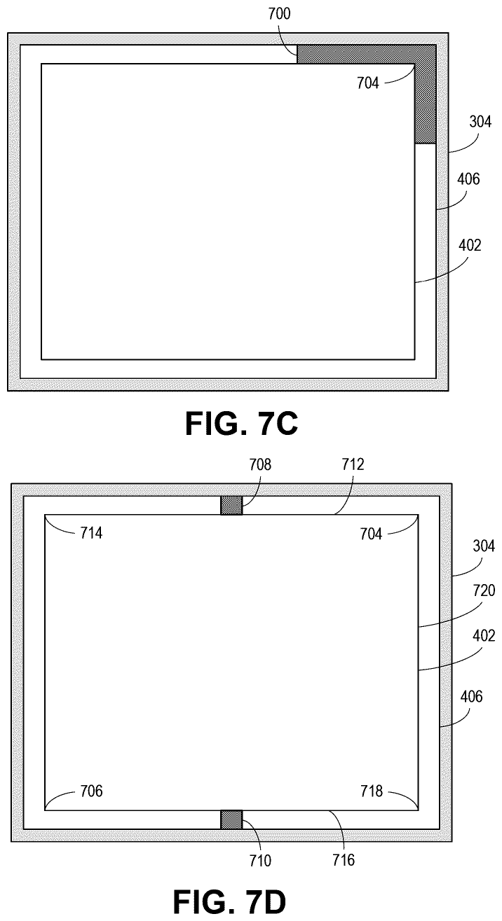

FIG. 5 is an example third implementation 500 of the IC package 106 of FIGS. 1, 2A, and 2B. The example third implementation 500 of FIG. 5 is similar to the example first implementation 300 of FIG. 3. However, the example third implementation 500 of FIG. 5 further includes an example stiffener 502 on the surface 306 of the package substrate 304. In the example of FIG. 5, the stiffener 502 is positioned between the dampener 120 and the package substrate 304.

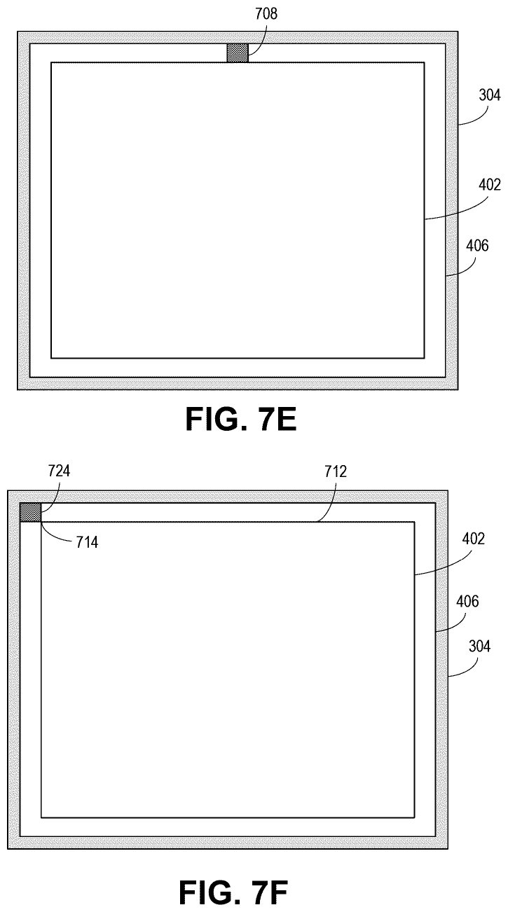

FIG. 6 is an example fourth implementation 600 of the example IC package 106 of FIGS. 1, 2A, and 2B. The example IC package 106 in the fourth implementation 600 in FIG. 6 is in contact with lateral sides of the dampener 120. Any of the components described in connection with FIGS. 3-5 may be included in the fourth implementation 600 of FIG. 6. For example, the dampener 120 in FIG. 6 can contact the side 312 of the semiconductor die 302. Further, the dampener 120 in FIG. 6 can contact the side 312 of the semiconductor die 302 and the stiffener 502. Additionally, the dampener 120 in FIG. 6 can contact a side of the IHS 402. Further, as shown in FIG. 4, the dampener 120 is spaced apart from (e.g., laterally inset relative to) an outer edge 408 of the IHS 402. However, in other examples, as shown in FIG. 6, the dampener 120 extends out to (e.g., is flush with and/or extends laterally beyond) the outer edge 408 of the IHS 402. Additionally or alternatively, in some examples, the dampener 120 extends out to (e.g., is flush with and/or extends laterally beyond) an outer edge 602 of the package substrate 304. In other examples, the dampener 120 is spaced apart from (e.g., laterally inset relative to) the outer edge 602 of the package substrate 304.

FIGS. 7A-7I are top views of different example implementations of the example package substrate 304, the example dampener 120, the example IC package 106, and the example IHS 402. More particularly, the examples of FIGS. 7A-7I illustrate orientations, positions, locations, patterns, etc., of the example dampener 120 (and/or other example dampers) relative to the example IC package 106. For purposes of explanation, the examples of FIGS. 7A-7I are described in connection with the second implementation 400 (including the IHS 402) and the fourth implementation 600 (having the dampener 120 in contact with a side of the IHS 402). However, any of the example implementations 300, 400, 500, 600 may be altered to demonstrate the examples of FIGS. 7A-7I.

Turning to FIG. 7A, the example dampener 120 is positioned at a perimeter of the IHS 402. In the example of FIG. 7, the perimeter of the IHS 402 has a generally rectangular shape. Accordingly, the orientation of the dampener 120 also has a generally rectangular shape. Further, in the example of FIG. 7A, the dampener 120 is positioned on the ledge 406 such that the ledge 406 is covered by the dampener 120. In other words, the dampener 120 surrounds (e.g., completely surrounds, extend continuously around) the IHS 402 by extending along the ledge 406. If, for example, the IC package 106 does not include the IHS 402 (FIG. 3 and/or FIG. 5), the dampener 120 can surround the semiconductor die 302 on the surface 306 (FIG. 3) of the package substrate 304. For example, the dampener 120 can be positioned at a perimeter of the package substrate 304 (e.g., having a generally rectangular shape).

In FIG. 7B, a plurality of example dampeners 700, 702 are positioned at different locations around the IC package 106. For example, the dampener 700 and the dampener 702 are positioned at different locations on the ledge 406 of the IHS 402. The example dampener 700 is positioned adjacent (e.g., at) a first corner 704 of the IHS 402 and the example dampener 702 is positioned adjacent a second corner 706 of the IHS 402. As such, the example dampener 700 and the dampener 702 are spaced apart from one another on the ledge 406. Further, the example dampener 700 and the dampener 702 at least partially surround the semiconductor die 302 that is underneath the IHS 402. In other examples, the dampener 700 and the dampener 702 can surround (e.g., partially surround) the semiconductor die 302 on the surface 306 of the package substrate 304 (e.g., in examples where the IHS 402 is removed such as FIG. 3, FIG. 5, etc.). For example, the dampener 700 may be positioned adjacent a first corner of the package substrate 304 and the dampener 702 may be positioned adjacent a second corner of the package substrate 304. In the example of FIG. 7B, the two dampeners 700, 702 are shown. However, the example IC package 106 may have any number of associated dampeners (e.g., at least 2, 3, 4, 10, etc.). As such, multiple ones of the dampeners 700, 702 may be spaced apart from one another on the ledge 406 to surround the IHS 402 (e.g., and the underlying semiconductor die 302). Similarly, multiple ones of the dampeners 700, 702 may be spaced apart from one another on the surface 306 of the package substrate 304 to surround the semiconductor die 302. Alternatively, one of the dampeners 700, 702 may be removed and/or otherwise excluded (see FIG. 7C having only the dampener 700).

In FIG. 7D, example dampeners 708, 710 are positioned at different locations around the IC package 106. For example, the dampener 708 and the dampener 710 are positioned at different locations on the ledge 406 of the IHS 402. The example dampener 708 is positioned adjacent a side 712 of the IHS 402 and spaced apart from the first corner 704 and a third corner 714 of the IHS 402. Similarly, the example dampener 710 is positioned adjacent another side 716 of the IHS 402 and spaced apart from the second corner 706 and a fourth corner 718 of the IHS 402. In some examples, the dampeners 708, 710 are positioned relative to the semiconductor die 302. For example, the dampener 708 is adjacent a side of the semiconductor die 302 and spaced apart from a corner of the semiconductor die 302.

FIG. 7D includes the two dampeners 708, 710. However, one of the dampeners 708, 710 may be removed (see FIG. 7E including only the dampener 708). Alternatively, additional dampeners may be positioned on other sides 720, 722 of the IHS 402 such that the underlying semiconductor die 302 is surrounded by 4 dampeners, one on each of the sides 712, 716, 720, 722. In FIG. 7F, example dampener 724 is positioned adjacent the third corner 714 and spaced apart from the side 712 of the IHS 402. The dampener 724 may be positioned adjacent a corner of the semiconductor die 302 and spaced apart from a side of the semiconductor die 302. Further, additional dampers may be positioned adjacent the other corners 704, 706, 718 (see FIG. 7G including four dampeners 724, 726, 728, 730 adjacent the corners 704, 706, 714, 718). The example dampeners 708, 710, 724, 726, 728, 730 of FIGS. 7D-7G exhibit a generally cubical shape.

FIG. 7H includes example dampeners 732, 734. The example dampeners 732, 734 of FIG. 7H are similar to the example dampeners 708, 710 of FIG. 7D. However, the example dampeners 732, 734 are different in size and shape than the example dampeners 708, 710. For example, the dampener 732 extends a first length across the side 712 of the IHS 402, whereas the dampener 708 extends a second length across the side 716, the second length less than the first length. As such, the example dampener 732 exhibits a generally rectangular prismatic shape (different from the generally cubical shape of the dampener 708 of FIG. 7D). The example dampener 734 extends a third length across the side 716 of the IHS 402, the third length less than the first length and greater than the second length. As such, the example dampener 734 also exhibits a generally rectangular prismatic shape. Further, any of the example dampeners disclosed herein (e.g., the dampener 120, the dampeners 700, 702, 708, 710, 724, 726, 728, 730 732, 734) can extend any length across the ledge 406, the surface 306, etc. FIG. 7H includes the two dampeners 732, 734. However, one of the dampeners 732, 734 may be removed (see FIG. 7I including only the dampener 732). Alternatively, additional dampeners may be positioned on the other sides 720, 722 of the IHS 402 such that the underlying semiconductor die 302 is surrounded by 4 dampeners.

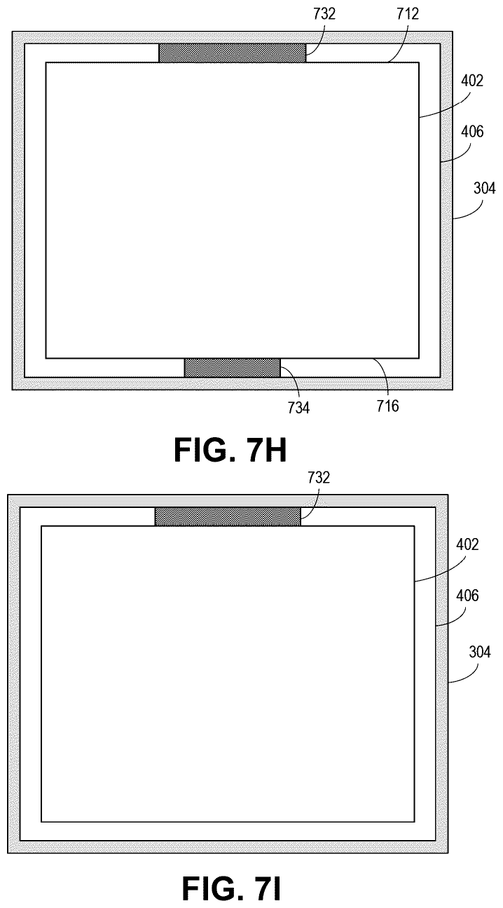

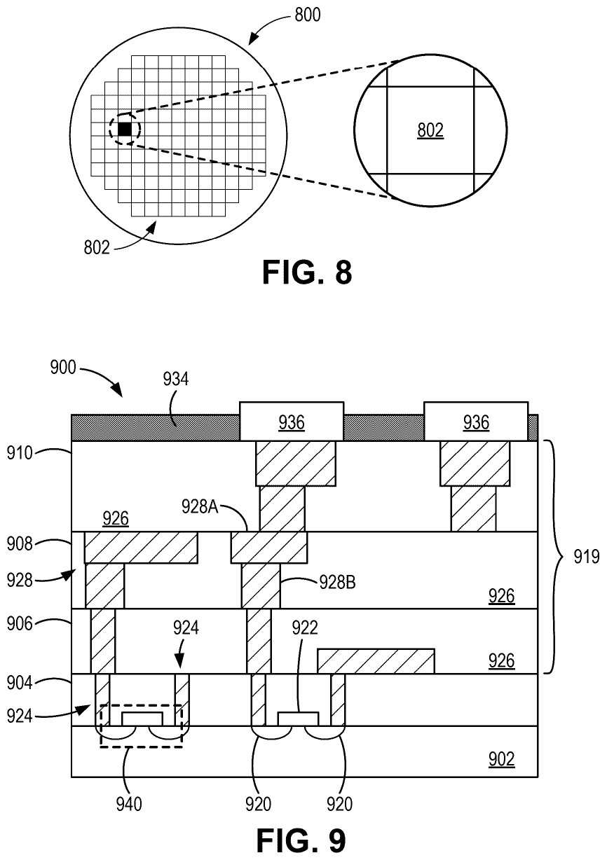

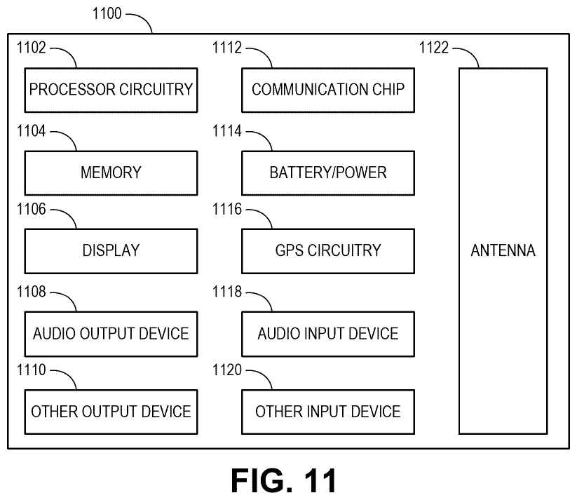

The example IC package 106 (in any of the example implementations 300, 400, 500, 600) disclosed herein may be included in any suitable electronic component. FIGS. 8-11 illustrate various examples of apparatus that may include or be included in the IC package 106 (in any of the example implementations 300, 400, 500, 600) disclosed herein. FIG. 8 is a top view of a wafer 800 and dies 802 that may be included in the IC package 106 (e.g., as the die 302). The wafer 800 includes semiconductor material and one or more dies 802 having circuitry. Each of the dies 802 may be a repeating unit of a semiconductor product. After the fabrication of the semiconductor product is complete, the wafer 800 may undergo a singulation process in which the dies 802 are separated from one another to provide discrete “chips.” The die 802 includes one or more transistors (e.g., some of the transistors 940 of FIG. 9, discussed below), supporting circuitry to route electrical signals to the transistors, passive components (e.g., traces, resistors, capacitors, inductors, and/or other circuitry), and/or any other components. In some examples, the die 802 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 802. For example, a memory array of multiple memory circuits may be formed on a same die 802 as programmable circuitry (e.g., the programmably circuitry 1102 of FIG. 11) and/or other logic circuitry. Such memory may store information for use by the programmable circuitry. The example IC package 106 (in any of the example implementations 300, 400, 500, 600) disclosed herein may be manufactured using a die-to-wafer assembly technique in which some dies are attached to a wafer 800 that includes others of the dies, and the wafer 800 is subsequently singulated.

FIG. 9 is a cross-sectional side view of an IC device 900 that may be included in the example IC package 106 (in any of the example implementations 300, 400, 500, 600) (e.g., in the die 302). One or more of the IC devices 900 may be included in one or more dies 802 (FIG. 8). The IC device 900 may be formed on a die substrate 902 (e.g., the wafer 800 of FIG. 8) and may be included in a die (e.g., the die 802 of FIG. 8). The die substrate 902 may be a semiconductor substrate including semiconductor materials including, for example, n-type or p-type materials systems (or a combination of both). The die substrate 902 may include, for example, a crystalline substrate formed using a bulk silicon or a silicon-on-insulator (SOI) substructure. In some examples, the die substrate 902 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an IC device 900 may be used. The die substrate 902 may be part of a singulated die (e.g., the dies 802 of FIG. 8) or a wafer (e.g., the wafer 800 of FIG. 8).

The IC device 900 may include one or more device layers 904 disposed on and/or above the die substrate 902. The device layer 904 may include features of one or more transistors 940 (e.g., metal oxide semiconductor field-effect transistors (MOSFETs)) formed on the die substrate 902. The device layer 904 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 940 may include a gate 922 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 940 along the source-channel-drain direction, the gate electrode may include a U-shaped structure that includes a bottom portion substantially parallel (e.g., within 5 degrees) to the surface of the die substrate 902 and two sidewall portions that are substantially perpendicular (e.g., within 5 degrees) to the top surface of the die substrate 902. In other examples, at least one of the metal layers that form the gate electrode may be a planar layer that is substantially parallel to the top surface of the die substrate 902 and does not include sidewall portions substantially perpendicular to the top surface of the die substrate 902. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of corresponding transistor(s) 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 920 may be formed using one or more alternate semiconductor materials such as germanium or a group III-V material or alloy. In further examples, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 2019 of the IC device 900.

The interconnect structures 928 may be arranged within the interconnect layers 906-910 to route electrical signals according to a wide variety of designs (in particular, the arrangement is not limited to the particular configuration of interconnect structures 928 depicted in FIG. 9). Although a particular number of interconnect layers 906-910 is depicted in FIG. 9, examples of the present disclosure include IC devices having more or fewer interconnect layers than depicted.

In some examples, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and/or out of the page from the perspective of FIG. 9. The vias 928b may be arranged to route electrical signals in a direction of a plane that is substantially perpendicular to the surface of the die substrate 902 upon which the device layer 904 is formed. In some examples, the vias 928b may electrically couple lines 928a of different interconnect layers 906-910 together.

The interconnect layers 906-910 may include a dielectric material 926 disposed between the interconnect structures 928, as shown in FIG. 9. In some examples, the dielectric material 926 disposed between the interconnect structures 928 in different ones of the interconnect layers 906-910 may have different compositions; in other examples, the composition of the dielectric material 926 between different interconnect layers 906-910 may be the same.

A first interconnect layer 906 (referred to as Metal 1 or “M1”) may be formed directly on the device layer 904. In some examples, the first interconnect layer 906 may include lines 928a and/or vias 928b, as shown. The lines 928a of the first interconnect layer 906 may be coupled with contacts (e.g., the S/D contacts 924) of the device layer 904.

A second interconnect layer 908 (referred to as Metal 2 or “M2”) may be formed directly on the first interconnect layer 906. In some examples, the second interconnect layer 908 may include vias 928b to couple the lines 928a of the second interconnect layer 908 with the lines 928a of the first interconnect layer 906. Although the lines 928a and the vias 928b are structurally delineated with a line within each interconnect layer (e.g., within the second interconnect layer 908) for the sake of clarity, the lines 928a and the vias 928b may be structurally and/or materially contiguous (e.g., simultaneously filled during a dual-damascene process) in some examples.

A third interconnect layer 910 (referred to as Metal 3 or “M3”) (and additional interconnect layers, as desired) may be formed in succession on the second interconnect layer 908 according to similar techniques and/or configurations described in connection with the second interconnect layer 908 or the first interconnect layer 906. In some examples, the interconnect layers that are “higher up” in the metallization stack 919 in the IC device 900 (i.e., further away from the device layer 904) may be thicker.

The IC device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to other external devices. For example, solder bonds may be formed on the one or more conductive contacts 936 to mechanically and/or electrically couple a chip including the IC device 900 with another component (e.g., a circuit board). The IC device 900 may include additional or alternate structures to route the electrical signals from the interconnect layers 906-910; for example, the conductive contacts 936 may include other analogous features (e.g., posts) that route the electrical signals to external components.

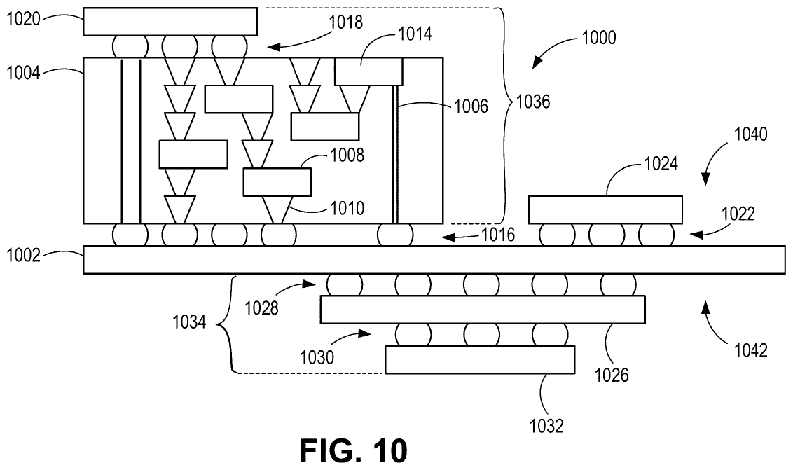

FIG. 10 is a cross-sectional side view of an IC device assembly 1000 that may include the IC package 106 (in any of the example implementations 300, 400, 500, 600) disclosed herein. In some examples, the IC device assembly corresponds to the IC package 106 (in any of the example implementations 300, 400, 500, 600). The IC device assembly 1000 includes a number of components disposed on a circuit board 1002 (which may be, for example, a motherboard). The IC device assembly 1000 includes components disposed on a first face 1040 of the circuit board 1002 and an opposing second face 1042 of the circuit board 1002; generally, components may be disposed on one or both faces 1040 and 1042. Any of the IC packages discussed below with reference to the IC device assembly 1000 may take the form of the example IC package 106 (in any of the example implementations 300, 400, 500, 600).

In some examples, the circuit board 1002 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1002. In other examples, the circuit board 1002 may be a non-PCB substrate.

The IC device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), male and female portions of a socket, an adhesive, an underfill material, and/or any other suitable electrical and/or mechanical coupling structure.

The package-on-interposer structure 1036 may include an IC package 1020 coupled to an interposer 1004 by coupling components 1018. The coupling components 1018 may take any suitable form for the application, such as the forms discussed above with reference to the coupling components 1016. Although a single IC package 1020 is shown in FIG. 10, multiple IC packages may be coupled to the interposer 1004; indeed, additional interposers may be coupled to the interposer 1004. The interposer 1004 may provide an intervening substrate used to bridge the circuit board 1002 and the IC package 1020. The IC package 1020 may be or include, for example, a die (the die 802 of FIG. 8), an IC device (e.g., the IC device 900 of FIG. 9), or any other suitable component. Generally, the interposer 1004 may spread a connection to a wider pitch or reroute a connection to a different connection. For example, the interposer 1004 may couple the IC package 1020 (e.g., a die) to a set of BGA conductive contacts of the coupling components 1016 for coupling to the circuit board 1002. In the example illustrated in FIG. 10, the IC package 1020 and the circuit board 1002 are attached to opposing sides of the interposer 1004; in other examples, the IC package 1020 and the circuit board 1002 may be attached to a same side of the interposer 1004. In some examples, three or more components may be interconnected by way of the interposer 1004.

In some examples, the interposer 1004 may be formed as a PCB, including multiple metal layers separated from one another by layers of dielectric material and interconnected by electrically conductive vias. In some examples, the interposer 1004 may be formed of an epoxy resin, a fiberglass-reinforced epoxy resin, an epoxy resin with inorganic fillers, a ceramic material, or a polymer material such as polyimide. In some examples, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through-silicon vias (TSVs) 1006. The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The IC device assembly 1000 may include an IC package 1024 coupled to the first face 1040 of the circuit board 1002 by coupling components 1010. The coupling components 1010 may take the form of any of the examples discussed above with reference to the coupling components 1016, and the IC package 1024 may take the form of any of the examples discussed above with reference to the IC package 1020.

The IC device assembly 1000 illustrated in FIG. 10 includes a package-on-package structure 1034 coupled to the second face 1042 of the circuit board 1002 by coupling components 1028. The package-on-package structure 1034 may include a first IC package 1026 and a second IC package 1032 coupled together by coupling components 1030 such that the first IC package 1026 is disposed between the circuit board 1002 and the second IC package 1032. The coupling components 1028, 1030 may take the form of any of the examples of the coupling components 1016 discussed above, and the IC packages 1026, 1032 may take the form of any of the examples of the IC package 1020 discussed above. The package-on-package structure 1034 may be configured in accordance with any of the package-on-package structures known in the art.

FIG. 11 is a block diagram of an example electrical device 1100 that may include one or more of the example IC package 106 (in any of the example implementations 300, 400, 500, 600). For example, any suitable ones of the components of the electrical device 1100 may include one or more of the device assemblies 1000, IC devices 900, or dies 802 disclosed herein, and may be arranged in the example IC package 106 (in any of the example implementations 300, 400, 500, 600). A number of components are illustrated in FIG. 11 as included in the electrical device 1100, but any one or more of these components may be omitted or duplicated, as suitable for the application. In some examples, some or all of the components included in the electrical device 1100 may be attached to one or more motherboards. In some examples, some or all of these components are fabricated onto a single system-on-a-chip (SoC) die.

Additionally, in various examples, the electrical device 1100 may not include one or more of the components illustrated in FIG. 11, but the electrical device 1100 may include interface circuitry for coupling to the one or more components. For example, the electrical device 1100 may not include a display 1106, but may include display interface circuitry (e.g., a connector and driver circuitry) to which a display 1106 may be coupled. In another set of examples, the electrical device 1100 may not include an audio input device 1118 (e.g., microphone) or an audio output device 1108 (e.g., a speaker, a headset, earbuds, etc.), but may include audio input or output device interface circuitry (e.g., connectors and supporting circuitry) to which an audio input device 1118 or audio output device 1108 may be coupled.

The electrical device 1100 may include programmable circuitry 1102 (e.g., one or more processing devices). The programmable circuitry 1102 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1100 may include a memory 1104, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1104 may include memory that shares a die with the programmable circuitry 1102. This memory may be used as cache memory and may include embedded dynamic random access memory (eDRAM) or spin transfer torque magnetic random access memory (STT-MRAM).

In some examples, the electrical device 1100 may include a communication chip 1112 (e.g., one or more communication chips). For example, the communication chip 1112 may be configured for managing wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1112 may operate in accordance with other wireless protocols in other examples. The electrical device 1100 may include an antenna to facilitate wireless communications and/or to receive other wireless communications (such as AM or FM radio transmissions).

In some examples, the communication chip 1112 may manage wired communications, such as electrical, optical, or any other suitable communication protocols (e.g., the Ethernet). As noted above, the communication chip 1112 may include multiple communication chips. For instance, a first communication chip 1112 may be dedicated to shorter-range wireless communications such as Wi-Fi or Bluetooth, and a second communication chip 1112 may be dedicated to longer-range wireless communications such as global positioning system (GPS), EDGE, GPRS, CDMA, WiMAX, LTE, EV-DO, or others. In some examples, a first communication chip 1112 may be dedicated to wireless communications, and a second communication chip 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display 1106 (or corresponding interface circuitry, as discussed above). The display 1106 may include any visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any device that generates an audible indicator, such as speakers, headsets, or earbuds.

The electrical device 1100 may include an audio input device 1118 (or corresponding interface circuitry, as discussed above). The audio input device 1118 may include any device that generates a signal representative of a sound, such as microphones, microphone arrays, or digital instruments (e.g., instruments having a musical instrument digital interface (MIDI) output).

The electrical device 1100 may include GPS circuitry 1116. The GPS circuitry 1116 may be in communication with a satellite-based system and may receive a location of the electrical device 1100, as known in the art.

The electrical device 1100 may include any other output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include any other input device 1120 (or corresponding interface circuitry, as discussed above). Examples of the other input device 1120 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1100 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide dampeners (e.g., dampening bodies, compressibly resilient materials, etc.) for use in socket-based architectures to mitigate risk of damage to pad surfaces. Examples disclosed herein position dampeners to resist movement of an example socket substrate and, thus, associated pins. For example, disclosed examples include dampeners that are positioned to interface with an example heatsink to resist movement of such a substrate. Accordingly, examples disclosed herein reduce and/or eliminate fretting on pad surfaces by dampening vibrations in an associated IC package. Examples disclosed herein improve the electrical connectivity in such an IC package by increasing the number of socket pins and mitigating fretting between the socket pins and any associated pad surfaces.

Example 1 includes an apparatus comprising a substrate, a semiconductor die carried by the substrate, and a dampener carried by the substrate, the dampener dimensioned to interface with a heatsink when the heatsink is thermally coupled to the semiconductor die.

Example 2 includes the apparatus of example 1, further including an integrated heat spreader enclosing the semiconductor die, the dampener coupled to the integrated heat spreader.

Example 3 includes the apparatus of any of example 1 or example 2, wherein the dampener is positioned at a perimeter of the integrated heat spreader.

Example 4 includes the apparatus of any of examples 1-3, wherein the integrated heat spreader includes a ledge that is recessed relative to an outer surface of the integrated heat spreader, the outer surface to interface with the heatsink, the dampener positioned on the ledge.

Example 5 includes the apparatus of any of examples 1-4, wherein the dampener extends farther away from the substrate than the outer surface of the integrated heat spreader is from the substrate.

Example 6 includes the apparatus of any of examples 1-5, wherein the dampener is positioned adjacent a side of the semiconductor die and spaced apart from a corner of the semiconductor die.

Example 7 includes the apparatus of any of examples 1-6, wherein the dampener is positioned adjacent a corner of the semiconductor die and spaced apart from a side of the semiconductor die.

Example 8 includes the apparatus of any of examples 1-7, wherein the dampener is coupled directly to the substrate via an adhesive.

Example 9 includes the apparatus of any of examples 1-8, wherein the semiconductor die is a bare die exposed on the substrate, a backside of the semiconductor die faces away from the substrate, and the dampener extends farther away from the substrate than the backside of the semiconductor die.

Example 10 includes the apparatus of any of examples 1-9, wherein substrate includes a first surface and a second surface opposite the first surface, the semiconductor die and the dampener on the first surface of the substrate.

Example 11 includes the apparatus of any of examples 1-10, further including a stiffener on the first surface of the substrate, the stiffener between the dampener and the substrate.

Example 12 includes the apparatus of any of examples 1-11, wherein the second surface of the substrate includes a ball grid array or a land grid array.

Example 13 includes the apparatus of any of examples 1-12, wherein the substrate is an interposer and the apparatus further includes a package substrate interconnecting the semiconductor die and the interposer.

Example 14 includes the apparatus of any of examples 1-14, wherein the dampener includes at least one of a foam, silicone, or polyurethane.

Example 15 includes an integrated circuit (IC) package comprising a substrate, a semiconductor die supported on a side of the substrate, and a compressibly resilient material supported on the side of the substrate, the compressibly resilient material laterally offset from the semiconductor die along the side of the substrate, the compressibly resilient material to resist movement of a heatsink relative to the semiconductor die when the heatsink is thermally coupled to the semiconductor die.

Example 16 includes the IC package of example 15, wherein the compressibly resilient material is to be held in compression between the substrate and the heatsink when the heatsink is thermally coupled to the semiconductor die.

Example 17 includes the IC package of any of example 15 or example 16, further including an integrated heat spreader separating the semiconductor die from the heatsink, wherein a portion of the integrated heat spreader extends across the side of the substrate to separate the compressibly resilient material from the substrate.

Example 18 includes an apparatus comprising a package substrate having a surface to support a semiconductor die, a heatsink coupled to the semiconductor die, and a dampening body compressed between the heatsink and the surface of the semiconductor substrate.

Example 19 includes the apparatus of example 18, wherein the dampening body surrounds the semiconductor die on the surface of the semiconductor substrate.

Example 20 includes the apparatus of any of example 18 or example 19, wherein the dampening body is one of at least two dampening bodies, the at least two dampening bodies spaced apart from one another to surround the semiconductor die on the surface of the semiconductor substrate.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a substrate;
a semiconductor die carried by the substrate; and
a dampener carried by the substrate, the dampener dimensioned to interface with a heatsink when the heatsink is thermally coupled to the semiconductor die.

2. The apparatus of claim 1, further including an integrated heat spreader enclosing the semiconductor die, the dampener coupled to the integrated heat spreader.

3. The apparatus of claim 2, wherein the dampener is positioned at a perimeter of the integrated heat spreader.

4. The apparatus of claim 2, wherein the integrated heat spreader includes a ledge that is recessed relative to an outer surface of the integrated heat spreader, the outer surface to interface with the heatsink, the dampener positioned on the ledge.

5. The apparatus of claim 4, wherein the dampener extends farther away from the substrate than the outer surface of the integrated heat spreader is from the substrate.

6. The apparatus of claim 1, wherein the dampener is positioned adjacent a side of the semiconductor die and spaced apart from a corner of the semiconductor die.

7. The apparatus of claim 1, wherein the dampener is positioned adjacent a corner of the semiconductor die and spaced apart from a side of the semiconductor die.

8. The apparatus of claim 1, wherein the dampener is coupled directly to the substrate via an adhesive.

9. The apparatus of claim 1, wherein the semiconductor die is a bare die exposed on the substrate, a backside of the semiconductor die faces away from the substrate, and the dampener extends farther away from the substrate than the backside of the semiconductor die.

10. The apparatus of claim 1, wherein substrate includes a first surface and a second surface opposite the first surface, the semiconductor die and the dampener on the first surface of the substrate.

11. The apparatus of claim 10, further including a stiffener on the first surface of the substrate, the stiffener between the dampener and the substrate.

12. The apparatus of claim 10, wherein the second surface of the substrate includes a ball grid array or a land grid array.

13. The apparatus of claim 1, wherein the substrate is an interposer and the apparatus further includes a package substrate interconnecting the semiconductor die and the interposer.

14. The apparatus of claim 1, wherein the dampener includes at least one of a foam, silicone, or polyurethane.

15. An integrated circuit (IC) package comprising:
a substrate;
a semiconductor die supported on a side of the substrate; and
a compressibly resilient material supported on the side of the substrate, the compressibly resilient material laterally offset from the semiconductor die along the side of the substrate, the compressibly resilient material to resist movement of a heatsink relative to the semiconductor die when the heatsink is thermally coupled to the semiconductor die.

16. The IC package of claim 15, wherein the compressibly resilient material is to be held in compression between the substrate and the heatsink when the heatsink is thermally coupled to the semiconductor die.

17. The IC package of claim 15, further including an integrated heat spreader separating the semiconductor die from the heatsink, wherein a portion of the integrated heat spreader extends across the side of the substrate to separate the compressibly resilient material from the substrate.

18. An apparatus comprising:
a package substrate having a surface to support a semiconductor die;
a heatsink coupled to the semiconductor die; and
a dampening body compressed between the heatsink and the surface of the semiconductor substrate.

19. The apparatus of claim 18, wherein the dampening body surrounds the semiconductor die on the surface of the semiconductor substrate.

20. The apparatus of claim 18, wherein the dampening body is one of at least two dampening bodies, the at least two dampening bodies spaced apart from one another to surround the semiconductor die on the surface of the semiconductor substrate.
